(19) United States
(12) Patent Application Publication
(10) Pub. No.: US 2015/0170968 A1
(43) Pub. Date: Jun. 18, 2015

(54) PACKAGE BOARD DIVISION METHOD

(71) Applicant: DISCO CORPORATION, Tokyo (JP)

(72) Inventor: Satoshi Sawaki, Tokyo (JP)

(21) Appl. No.: 14/560,082

(22) Filed: Dec. 4, 2014

(30) Foreign Application Priority Data
Dec. 16, 2013 (JP) 2013-259143

(51) Int. Cl. H01L 21/78; H01L 21/66

(52) U.S. Cl. CPC H01L 21/78; H01L 22/12

(57) ABSTRACT

A package board division method including: a step of detecting an index size between each two adjacent scheduled division lines from position coordinates of each of scheduled division lines, a step of determining whether the index size falls within the range of package device specification, a step of correcting the position coordinates of each of scheduled division lines in such a manner that the index size falls within the specification range if the index size falls outside the specification range, and a step of machining the package board along the detected scheduled division line when the index size falls within the specification range and machining the package board along the corrected scheduled division line when the index size falls outside the specification range.

### BACKGROUND OF THE INVENTION

1. Field of the Invention

The present invention relates to a division method of CSP (Chip Size Package), QFN (Quad Flat Non-leaded Package), or other package board.

2. Description of the Related Art

A CSP, QFN, or other package board has a plurality of semiconductor chips arranged thereon. Circuits such as IC and LSI are formed on each of these chips. These chips are sealed, for example, with mold resin and formed in an approximately rectangular plate shape. The package board is cut along scheduled division lines by a cutting device into packages each of which is of approximately the same size as a semiconductor chip. The positions of the scheduled division lines are distorted due, for example, to expansion or contraction of the circuit board during resin molding. During cutting, therefore, so-called detection and alignment is used which is designed to determine the cutting positions from the results of alignment of the scheduled division lines (refer, for example, to Japanese Patent Laid-open No. 2002-033295).

### SUMMARY OF THE INVENTION

However, although detection and alignment described in Japanese Patent Laid-open No. 2002-033295 permits cutting along scheduled division lines, package sizes may fall outside the size tolerance (package size tolerance) and go out of specification in the event of displacement of scheduled division lines due, for example, to expansion or contraction of the board. For example, if the package device is a CPU (Central Processing Unit), and if the package size falls significantly outside the size tolerance and goes out of specification, the CPU cannot be placed into the socket of the motherboard.

In light of the foregoing, it is an object of the present invention to provide a package board division method that allows for division of a package board into individual package devices in such a manner that the package size falls within a size tolerance.

In accordance with an aspect of the present invention, there is provided a package board division method for dividing a package board into individual package devices. The plurality of package devices are formed in such a manner as to be partitioned by scheduled division lines into a given number of subsets. The package board division method includes a detection step, a determination step, and a division step. The detection step detects position coordinates of each of scheduled division lines and an index size between each two adjacent scheduled division lines using imaging means. The determination step determines whether the detected index size falls within the range of a package size tolerance following the detection step. The division step divides, by machining means, the package board into each of the package devices based on the index size and the position coordinates of each of the scheduled division lines detected in the detection step when it is determined in the determination step that the index size falls within the range of the package size tolerance.

According to this configuration, a package board is divided into individual package devices when the index size between scheduled division lines falls within a package size tolerance. This ensures that package devices remain within specification after division even in the event of displacement of scheduled division lines due, for example, to expansion or contraction of the package board.

Further, in the package board division method according to the present invention, if it is determined in the determination step that the index size falls outside the range of the package size tolerance, a correction step is performed. The correction step corrects the position coordinates of each of the scheduled division lines within the bounds of the scheduled division line in such a manner that the index size falls within the range of the package size tolerance. The division step divides the package board into the package devices based on the post-correction index size and the post-correction position coordinates of the scheduled division line. The division step is cancelled if, in the correction step, the position coordinates of each of the scheduled division lines cannot be corrected within the bounds of the scheduled division line in such a manner that the index size falls within the range of the package size tolerance.

The present invention allows for division of a package board in such a manner that each of package devices remains within specification even in the event of expansion or contraction of the package board by correcting the position coordinates of each of the scheduled division lines so that the index size falls within the range of the package size tolerance.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view of a cutting device according to a present embodiment;

FIGS. 2A to 2C are explanatory diagrams of all point alignment according to the present embodiment;

FIGS. 3A to 3C are explanatory diagrams of two point alignment according to the present embodiment; and

FIG. 4 illustrates a flowchart of a package board division method according to the present embodiment.

### DETAILED DESCRIPTION OF THE PREFERRED EMBODIMENT

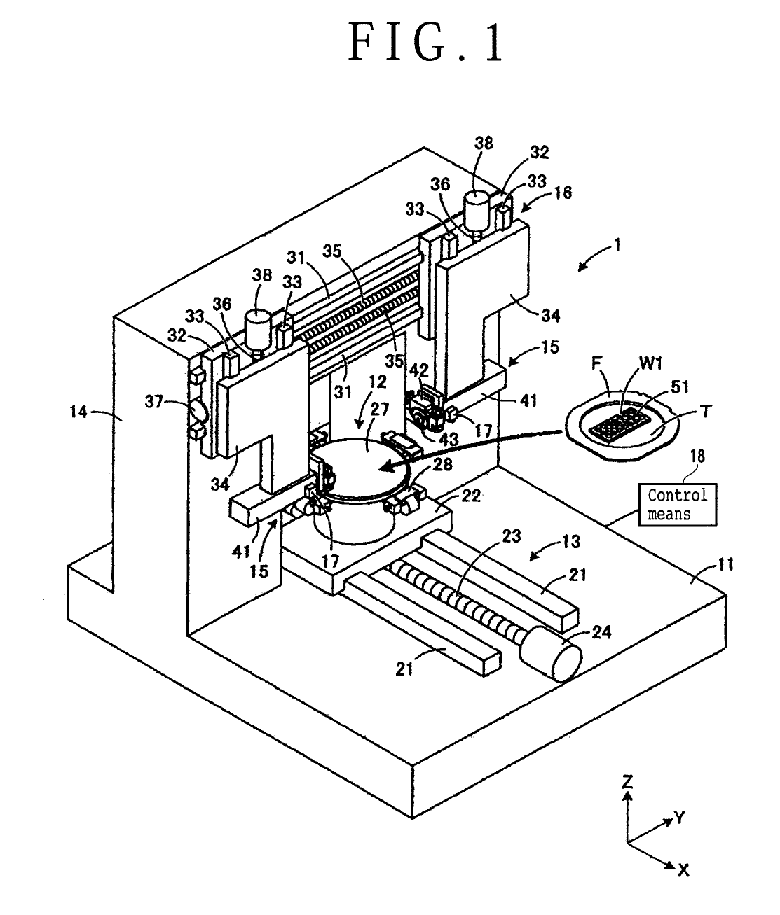

A description will be given below of a cutting device according to a present embodiment with reference to the accompanying drawings. FIG. 1 is a perspective view of the cutting device according to the present embodiment. It should be noted that the cutting device according to the present embodiment is not limited to the configuration shown in FIG. 1. The present invention is applicable to any kind of cutting device so long as the cutting device can cut a package board.

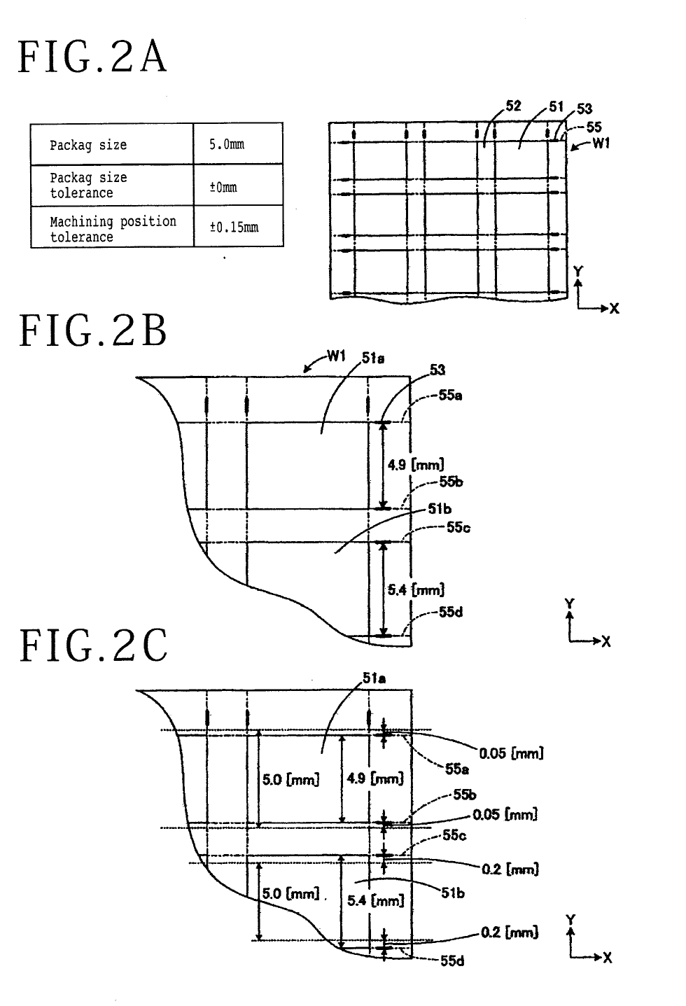

A cutting device 1 shown in FIG. 1 is configured so that it aligns machining means 15 relative to a package board W1 first and then divides the package board W1 into individual package devices 51. The package board W1 shown in FIG. 2A is formed in an approximately rectangular plate shape and partitioned into the plurality of package devices 51 by scheduled division lines 55 arranged in a grid pattern. The plurality of package devices 51 are formed on the package board W1 with a given spacing therebetween. A marginal area 52, an excess portion, is provided around each of the individual devices 51. Each of the package devices 51 is sealed with mold resin from the back.

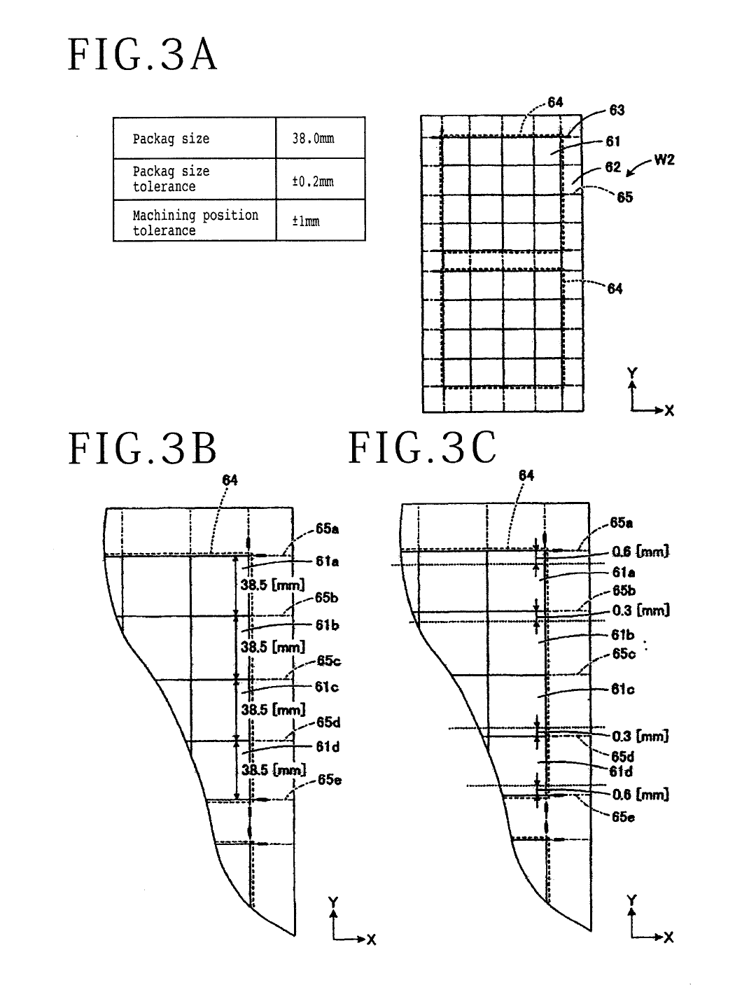

Further, alignment targets 53 are provided on the package board W1 to detect index sizes between the scheduled division lines 55. The alignment targets 53 define the vertical and horizontal sizes of each of the package devices 51 and are provided in the outer perimeter portions of the package board W1 to match the vertical and horizontal sides of each of the package devices 51. The package board W1 is subjected to so-called all point alignment which is designed to detect the alignment targets 53 for each of the package devices 51. It should be noted that although FIG. 1 illustrates the package board W1 shown in FIG. 2A, a package board W2 shown in FIG. 3A may be used instead.

A plurality of device formation areas 64 are formed on the package board W2 shown in FIG. 3A. Each of the device formation areas 64 is partitioned into a plurality of package devices 61 by scheduled division lines 65. Therefore, the plurality of package devices 61 are arranged in each of the device formation areas 64 with no spacing therebetween. A marginal area 62 is provided only around each of the device formation areas 64. Alignment targets 63 of the package board W2 define the vertical and horizontal sizes of each of the package devices 61 and are provided in the outer perimeter portion of the package board W2 to match the vertical and horizontal sides of each of the package devices 61 (only the alignment targets 63 at the four corners of each of the device formation areas 64 are shown here). The package board W2 is subjected to so-called two point alignment which is designed to detect the alignment targets 63 for each of the device formation areas 64.

Referring back to FIG. 1, a holding tape T is affixed to the rear face of the package board W1. An annular frame F is affixed to the outer perimeter of the holding tape T. The package board W1 is loaded onto the cutting device 1 in a manner supported by the annular frame F via the holding tape T. It should be noted that the package board W1 is not limited to a chip-mounted board such as CSP (Chip Size Package) or QFN (Quad Flat Non-leaded Package) and may be a board to which chips have yet to be mounted. A moving mechanism 13 is provided on a base 11 of the cutting device 1 to feed a chuck table 12 in the X-axis direction for machining. The chuck table 12 holds the package board W1.

The moving mechanism 13 has a pair of guide rails 21 that are arranged on the base 11 to be parallel to each other in the X-axis direction. The moving mechanism 13 also has a motor-driven X-axis table 22 that is slidably installed to the pair of guide rails 21. The chuck table 12 is provided above the X-axis table 22. A nut section that is not shown is provided on the rear side of the X-axis table 22. A ball screw 23 is screwed into the nut section. Then, a driving motor 24 is connected to one end of the ball screw 23. The ball screw 23 is driven to rotate by the driving motor 24, causing the chuck table 12 to move in the X-axis direction along the guide rails 21.

A holding face 27 made of a porous ceramic material is formed on the surface of the chuck table 12. The package board W1 is sucked and held by a negative pressure taking place on the holding face 27. Four pneumatically driven clamp sections 28 are provided around the chuck table 12, and the annular frame F around the package board W1 is sandwiched and held by the clamp sections 28. Further, an upright gate-shaped pole section 14 is provided on the base 11 in such a manner as to straddle the moving mechanism 13. A moving mechanism 16 is provided on the pole section 14 to index the pair of machining means 15 in the Y-axis direction above the chuck table 12 and raise or lower the machining means 15 in the Z-axis direction.

The moving mechanism 16 has a pair of guide rails 31 that are parallel to the front face of the pole section 14 in the Y-axis direction. The moving mechanism 16 also has a pair of motor-driven Y-axis tables 32 that are slidably installed to the pair of guide rails 31. Further, the moving mechanism 16 has a pair of guide rails 33 that are arranged on the front face of each of the Y-axis tables 32 and parallel to the Z-axis direction. The moving mechanism 16 also has a motor-driven Z-axis table 34 slidably installed to each pair of the guide rails 33. One of the machining means 15 is provided under each of the Z-axis tables 34 to cut the package board W1 with a cutting blade 43 and divide the package board W1 along the scheduled division lines 55 (refer to FIG. 2A).

A nut section that is not shown is formed on the rear side of each of the Y-axis tables 32. A ball screw 35 is screwed into each of the nut sections. Further, a nut section that is not shown is formed on the rear side of each of the Z-axis tables 34. A ball screw 36 is screwed into each of the nut sections. Driving motors 37 and 38 are connected to one ends of the ball screws 35 for the Y-axis tables 32 and the ball screws 36 for the Z-axis tables 34, respectively. The ball screws 35 and 36 are driven to rotate by the driving motors 37 and 38, causing the pair of machining means 15 to move in the Y and Z-axis directions along the guide rails 31 and 33.

The cutting blade 43 is fitted to a distal end of a spindle 41 of each of the pair of machining means 15. Each of the cutting blades 43 is covered with a blade cover 42. Injection nozzles are provided on the blade cover 42 to inject a cutting fluid onto cutting areas. Further, an imaging means 17 is provided on each of the spindles 41, aligning the cutting blade 43 with the scheduled division lines 55 (refer to FIG. 2A) of the package board W1 based on a captured image of the imaging means 17. With the machining means 15, a cutting fluid is injected from a plurality of nozzles. The package board W1 is cut along the scheduled division lines 55 by the cutting blades 43, dividing the package board W1 into the individual package devices 51.

Further, a control means 18 is provided in the cutting device 1 to control the respective sections of the cutting device 1 in an integrated manner. The control means 18 includes a processor adapted to perform a variety of processing tasks, a memory, and so on. The memory includes one or a plurality of storage media such as ROM (Read Only Memory) and RAM (Random Access Memory) to suit the purpose of application. The memory stores not only a variety of cutting conditions of the cutting device 1 but also a program for alignment of the cutting blades 43 with respect to the package board W1, e.g., a program for all point alignment, a program for two point alignment, a correction process program which will be described later, and so on.

Incidentally, the package board W1 is molded with the rear side of the package devices 51 sealed with mold resin. As a result, the scheduled division lines 55 (refer to FIG. 2A) may be displaced due to expansion or contraction of the board as a whole. For this reason, the cutting device 1 according to the present embodiment corrects the position coordinates of the scheduled division lines 55 in consideration of possible expansion or contraction during sealing of the package board W1 with mold resin so that the package devices 51 fall within the size specification limits. A description will be given below of all point alignment using the package board W1 shown in FIG. 2A and two point alignment using the package board W2 shown in FIG. 3A.

It should be noted that all point alignment provides the highest machining position accuracy because all index sizes must be measured. However, this alignment is time-consuming. On the other hand, two point alignment takes a shorter time than all point alignment. However, two point alignment offers lower machining position accuracy. Therefore, it is preferable to determine which of these alignment techniques should be used in consideration of alignment time and machining position accuracy.

FIGS. 2A to 2C are explanatory diagrams of all point alignment according to the present embodiment. FIGS. 3A to 3C are explanatory diagrams of two point alignment according to the present embodiment. It should be noted that although alignment of the scheduled division lines in the X-axis direction will be described here, the same is true for alignment of the scheduled division lines in the Y-axis direction. Further, in the package board W2 shown in FIGS. 3A to 3C, only the alignment targets 63 at the four corners of each of the device formation areas 64 are shown for reasons of description. However, the alignment targets 63 are provided in the outer perimeter portions of all the scheduled division lines 65. Still further, each of FIGS. 2A and 3A illustrates merely an example of each alignment process, and the present invention is not limited to these configurations.

A description will be given first of all point alignment. As illustrated in FIG. 2A, the package board W1 has the plurality of rectangular package devices 51 that are arranged with a spacing therebetween as described above. The vertical package size (size along the Y-axis direction) of each of the package devices 51 is set to 5.0 mm. The package size tolerance is set to ±0 mm, and the machining position tolerance is set to ±0.15 mm. The term “package size” refers to the preset design value of the package device 51. The term “package size tolerance” refers to the specification limit of the package device 51. The term “machining position tolerance” refers to the correction limits of the position coordinates of the scheduled division lines 55 within which the package performance can be maintained.

Further, the scheduled division lines 55 according to the present embodiment each have a given width equal to the sum of the design blade width of the cutting blade 43 (refer to FIG. 1) and the machining position tolerance. Therefore, the bounds of the scheduled division line 55 represent the bounds within which the package performance can be maintained when the package board W1 is cut with the cutting blade 43.

In this case, the package device 51 is considered in specification when the actual index size of the package device 51 (measured result) falls within the range of the package size tolerance for the package size. Even if the actual index size of the package device 51 exceeds the package size tolerance, but if the amount by which the index size exceeds the tolerance falls within the range of the machining position tolerance for the package size, it is possible to correct the position coordinates of the scheduled division line 55 (machining position) so as to bring the position coordinates within the range of the package size tolerance. It should be noted that so long as the position coordinates are corrected within the range of the machining position tolerance, the package device 51 will not decline in package performance after division.

In all point alignment, the alignment targets 53 located in the outer perimeter portions of the package board W1 are imaged by the imaging means 17 (refer to FIG. 1), detecting the position coordinates of the scheduled division lines 55. The index size between the scheduled division lines 55, the vertical size of the package device 51, is detected from the position coordinates of the scheduled division lines 55. The package size is compared against the index size to calculate the amount by which the index size, the measured value, exceeds the package size, the design value. Then, it is determined whether the amount by which the index size exceeds the package size falls within the range of the package size tolerance, the specification limit.

When the amount by which the index size exceeds the package size falls within the range of the package size tolerance, cutting is performed based on the current index size and the current position coordinates of the scheduled division lines 55. On the other hand, if the amount by which the index size exceeds the package size falls outside the range of the package size tolerance, the position coordinates of the scheduled division lines 55 are corrected within the range of the machining position tolerance (within the bounds of the scheduled division lines 55). As a result, the corrected position coordinates of the scheduled division lines 55 fall within the range of the package size tolerance, and cutting is performed based on the corrected index size and the corrected position coordinates of the scheduled division lines 55. Further, if the amount by which the index size exceeds the package size cannot be corrected to fall within the range of the package size tolerance with the machining position tolerance, no cutting will be performed along the scheduled division lines 55.

In FIG. 2B, for example, the measured index size of a package device 51a is 4.9 mm, and the measured index size of a package device 51b is 5.4 mm. Because the package size is 5.0 mm, the index size of the package device 51a has decreased by 0.1 mm relative to the package size, and the index size of the package device 51b has increased by 0.4 mm relative to the package size. The increase and decrease in index size of the package devices 51a and 51b exceed the range of the package size tolerance of 0 mm. Therefore, the package devices 51a and 51b are both out of specification at present.

As illustrated in FIG. 2C, the index size of the package device 51a has decreased by 0.1 mm relative to the package size tolerance. Therefore, this decrease in index size can be corrected with the machining position tolerance of ±0.15 mm. In this case, the decrease in index size of each of a pair of scheduled division lines 55a and 55b is 0.05 mm. Therefore, the position coordinates of each of the scheduled division lines 55a and 55b are corrected in such a manner as to increase by 0.05 mm so that the decrease in index size is cancelled out. As a result, the position coordinates of the scheduled division lines 55a and 55b fall within the range of the package size tolerance, and cutting is performed along the corrected scheduled division lines 55a and 55b.

On the other hand, the index size of the package device 51b has increased by 0.4 mm relative to the package size tolerance. Therefore, this increase in index size cannot be corrected with the machining position tolerance of ±0.15 mm. In this case, the increase in index size of each of a pair of scheduled division lines 55c and 55d is 0.2 mm. Therefore, even if the position coordinates of each of the scheduled division lines 55c and 55d are corrected with the machining position tolerance (−0.075 mm) in such a manner as to decrease so that the increase in index size is cancelled out, the position coordinates do not fall within the range of the package size tolerance. In the division step of the package board W1, therefore, cutting is performed by ignoring the scheduled division lines 55c and 55d of the package device 51b.

A description will be given next of two point alignment. As illustrated in FIG. 3A, the package board W2 has the plurality of package devices 61 that are arranged in each of the device formation areas 64 with no spacing therebetween as described above. The vertical package size (size along the Y-axis direction) of each of the package devices 61 is set to 38.0 mm. The package size tolerance is set to ±0.2 mm, and the machining position tolerance is set to ±1.0 mm.

In two point alignment, the alignment targets 63 located at the four corners of each of the device formation areas 64 are imaged by the imaging means 17 (refer to FIG. 1), detecting the position coordinates of the scheduled division lines 65 of the device formation areas 64. The index size between the scheduled division lines 65, the vertical size of the device formation area 64, is detected from the position coordinates of the scheduled division lines 65. The index size of each of the package devices 61 is found by dividing the measured overall size of the device formation area 64 equally by the number of the package devices 61. Then, the package size is compared against the index size to determine whether the amount by which the index size exceeds the package size falls within the range of the package size tolerance, the specification limit.

When the amount by which the index size exceeds the package size falls within the range of the package size tolerance, cutting is performed based on the current index size and the current position coordinates of the scheduled division lines 65. On the other hand, if the amount by which the index size exceeds the package size falls outside the range of the package size tolerance, the position coordinates of the scheduled division lines 65 are corrected within the range of the machining position tolerance (within the bounds of the scheduled division lines 65). As a result, the corrected position coordinates of the scheduled division lines 65 fall within the range of the package size tolerance, and cutting is performed based on the corrected index size and the corrected position coordinates of the scheduled division lines 65. Further, if the amount by which the index size exceeds the package size cannot be corrected to fall within the range of the package size tolerance with the machining position tolerance, no cutting will be performed along the scheduled division lines 65.

In FIG. 3B, for example, the index size of the device formation area 64 is equally divided, and the index size of each of package devices 61a to 61d is 38.5 mm. Because the package size is 38.0 mm, the index size of each of the package devices 61a to 61d has increased by 0.5 mm relative to the package size. The increase in index size of each of the package devices 61a to 61d exceeds the range of the package size tolerance of ±0.2 mm by 0.3 mm. Therefore, the package devices 61a to 61d are all out of specification at present.

As illustrated in FIG. 3C, the index size of each of the package devices 61a to 61d has increased by 0.3 mm relative to the package size tolerance. The increase in index size of each of the package devices 61a to 61d can be corrected with the machining position tolerance of ±1.0 mm. In this case, the increase in index size of each of the package devices 61a to 61d is corrected relative to a scheduled division line 65c, the scheduled division line in the third row from top and at the center of all the scheduled division lines. That is, the position coordinates of the scheduled division line 65c at the center are not corrected, and those of the remaining scheduled division lines 65a, 65b, 65d, and 65e are corrected in such a manner as to cancel out the increase in index size of each of the package devices 61a to 61d.

The position coordinates of the scheduled division lines 65b and 65d in the second and fourth rows from top are corrected to decrease by 0.3 mm respectively. On the other hand, the position coordinates of the scheduled division lines 65a and 65e in the first and fifth rows from top are corrected to decrease by 0.6 mm in consideration of the correction amounts of the scheduled division lines 65b and 65d in the second and fourth rows from top. As a result, the position coordinates of the scheduled division lines 65a to 65d fall within the range of the package size tolerance, and cutting is performed along the corrected scheduled division lines 65.

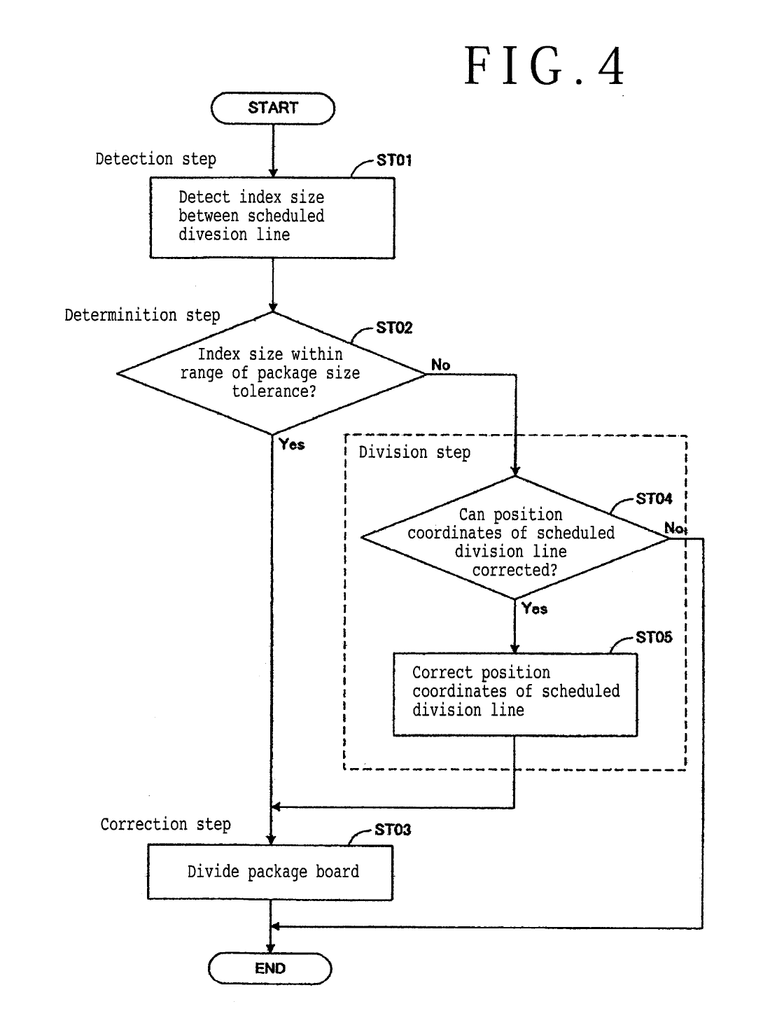

A description will be given here of the flow of the package board division method with reference to FIG. 4. FIG. 4 illustrates a flowchart of the package board division method according to the present embodiment. It should be noted that FIG. 4 illustrates an example of the package board division method, and that the package board division method is not limited to the content thereof. It should also be noted that the description will be given here by taking, as an example, a case in which the package board shown in FIG. 2A is divided.

As illustrated in FIG. 4, the detection step is performed first (step ST01). In the detection step, the position coordinates of each of the scheduled division lines 55 (refer to FIG. 2A) are detected by the imaging means 17 (refer to FIG. 1), thus detecting the index size between each two adjacent scheduled division lines 55. The determination step is performed following the detection step (step ST02). In the determination step, it is determined whether the index size detected in the detection step falls within the range of the package size tolerance. When it is determined in the determination step that the index size detected in the detection step falls within the range of the package size tolerance (Yes in step ST02), the division step is performed (step ST03). In the division step, the package board W1 is divided by the machining means 15 (refer to FIG. 1) based on the current index size and the current position coordinates of the scheduled division lines 55 detected in the detection step.

If it is determined in the determination step that the index size falls outside the range of the package size tolerance (No in step ST02), the correction step is performed (step ST04). In the correction step, it is determined whether the position coordinates of the scheduled division line 55 can be corrected within the bounds of the scheduled division lines 55 (within the range of the machining position tolerance) so that the index size falls within the range of the package size tolerance. When the scheduled division line 55 can be corrected in the correction step (Yes in step ST04), the position coordinates of the scheduled division line 55 are corrected (step ST05). Then, the division step is performed with the corrected position coordinates of the scheduled division line 55 (step ST03).

If the scheduled division line 55 cannot be corrected in the correction step (No in step ST04), the position coordinates of the scheduled division line 55 are not corrected, and the division step is cancelled for this scheduled division line 55. It should be noted that all the scheduled division lines 55 are subjected to the processes from step ST02 to step ST05. On the other hand, although the division method of the package board W1 according to the present embodiment has been described by taking, as an example, a case in which the correction step is performed, the present embodiment is not limited to this configuration. The division method of the package board W1 may not include the correction step. That is, cutting may be performed along the scheduled division line 55 only when the index size falls within the range of the package size tolerance in the determination step, and steps ST04 and ST05 may be omitted.

As described above, the division method of the package board W1 according to the present embodiment divides the package board W1 into the individual package devices 51 based on the current position coordinates of the scheduled division line 55 when the index size between the scheduled division lines 55 falls within the range of the package size tolerance. If the index size between the scheduled division lines 55 falls outside the range of the package size tolerance, the position coordinates of the scheduled division line 55 are corrected to the extent that the package performance is not affected. Then, the corrected index size between the scheduled division lines 55 falls within the range of the package size tolerance, and the package board W1 is divided into the individual package devices 51. In this case, the position coordinates of the scheduled division line 55 are not corrected to the extent that the package performance is affected. Even in the event of displacement of the scheduled division line 55 due to expansion or contraction of the package board W1, therefore, the divided package device 51 will not be out of specification, and moreover, the package performance will not decline. On the other hand, the same advantageous effect can be achieved with the package board W2.

It should be noted that the present invention is not limited to the above embodiment and may be changed in various ways. The above embodiment are not limited to the sizes and shapes shown in the accompanying drawings, and the sizes and shapes may be changed as appropriate to the extent that the advantageous effect of the present invention can be achieved. In addition, other changes may be made as appropriate to the present invention without departing from the scope of the present invention.

In the division method of the package board W1 according to the present embodiment, for example, it is determined in the correction step whether the position coordinates of the scheduled division lines 55 or 65 can be corrected within the bounds of the scheduled division line 55 or 65 (within the range of the machining position tolerance) so that the index size falls within the range of the package size tolerance. However, the present invention is not limited thereto. Instead, whether the position coordinates can be corrected may be determined in the determination step.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A package board division method for dividing a package board into individual package devices, the plurality of package devices being formed in such a manner as to be partitioned by scheduled division lines into a given number of subsets, the package board division method comprising:
a detection step of detecting position coordinates of each of scheduled division lines and an index size between each two adjacent scheduled division lines using imaging means;
a determination step of determining whether or not the detected index size falls within a range of a package size tolerance following the detection step; and
a division step of dividing, by machining means, the package board into each of the package devices based on the index size and the position coordinates of each of the scheduled division lines detected in the detection step when it is determined in the determination step that the index size falls within the range of the package size tolerance.

2. The package board division method of claim 1 further comprising
a correction step of correcting the position coordinates of each of the scheduled division lines within bounds of the scheduled division line in such a manner that the index size falls within the range of the package size tolerance if it is determined in the determination step that the index size falls outside the range of the package size tolerance,
wherein the division step divides the package board into the package devices based on the post-correction index size and the post-correction position coordinates of the scheduled division line, and
the division step is cancelled if, in the correction step, the position coordinates of each of the scheduled division lines cannot be corrected within the bounds of the scheduled division line in such a manner that the index size falls within the range of the package size tolerance.
